(19) United States
(12) Patent Application Publication
(10) Pub. No.: US 2025/0219004 A1
(43) Pub. Date: Jul. 3, 2025

(54) CONNECTING STRUCTURE

(71) Applicant: NITTO DENKO CORPORATION, Ibaraki-shi, Osaka (JP)

(72) Inventors: Masatoshi KATO, Ibaraki-shi, Osaka (JP); Tsubasa OMURA, Ibaraki-shi, Osaka (JP); Yuichiro SHISHIDO, Ibaraki-shi, Osaka (JP); Naofumi KOSAKA, Ibaraki-shi, Osaka (JP)

(21) Appl. No.: 18/851,980

(22) PCT Filed: Mar. 15, 2023
(86) PCT No.: PCT/JP2023/010140

§ 371 Date: Sep. 27, 2024

(30) Foreign Application Priority Data
Mar. 29, 2022 (JP) 2022-053342

(51) Int. Cl. H01L 23/00

(52) U.S. Cl. CPC H01L 24/29; H01L 24/16; H01L 24/32; H01L 24/73; H01L 24/81; H01L 24/83; H01L 24/92; H01L 2224/16148; H01L 2224/16238; H01L 2224/2929; H01L 2224/32145; H01L 2224/32225; H01L 2224/73204; H01L 2224/81935; H01L 2224/83203; H01L 2224/83855; H01L 2224/9201; H01L 2224/92143

(57) ABSTRACT

A connecting structure includes a first substrate having a plurality of first electrodes arranged in a plane direction; a second substrate having a plurality of second electrodes arranged in the plane direction and disposed at a spaced interval with respect to the first substrate in a thickness direction perpendicular to the plane direction so that the first electrode faces the second electrode; and an adhesive layer interposed between the first substrate and the second substrate, electrically connecting the first electrode and the second electrode facing each other in the thickness direction, and adhering the first substrate to the second substrate. A thickness of the adhesive layer is below 15 μm. A distance A between the first electrodes adjacent to each other In the plane direction is longer than a distance B between the first electrode and the second electrode facing each other in the thickness direction.

### TECHNICAL FIELD

The present invention relates to a connecting structure.

### BACKGROUND ART

Conventionally, in bonding between terminals of two wiring circuit boards, a film containing an anisotropic electrically conductive material has been used.

As such a film, for example, an electrically conductive film containing a binder resin, at least one kind of a curing agent and a curing accelerator, flux, and a plurality of solder particles has been proposed (ref: for example, Patent Document 1). In Patent Document 1, by using such an electrically conductive film, a first electrode and a second electrode which face each other in a thickness direction are bonded to each other, thereby producing a connecting structure.

Specifically, first, a first connecting object member including the plurality of first electrodes arranged in a plane direction and a second connecting object member including the plurality of second electrodes arranged in the plane direction are prepared. Next, the electrically conductive film is disposed so as to cover the surface of the first connecting object member provided with the first electrode, and further, the second connecting object member is disposed on the surface of the electrically conductive film so as to cover the surface of the second connecting object member provided with the second electrode. That is, the first electrode and the second electrode are disposed to face each other in the thickness direction. Next, the electrically conductive film is heated. Thus, the solder particles included in the electrically conductive film are melted, thereby forming a solder portion electrically connecting the first electrode to the second electrode. Thus, the connecting structure is produced.

### CITATION LIST

### Patent Document

Patent Document 1: Japanese Unexamined Patent Publication No. 2020-047590

### SUMMARY OF THE INVENTION

### Problem to be Solved by the Invention

In recent years, from the viewpoint of achieving a small size and a low height, the electrode has promoted a narrowing pitch, and there is a demand to reduce a mounting thickness. However, when the thick film is forcibly thinly mounted (such as pressurized) on the electrode disposed at the narrowed pitch, the melted solder particles electrically connect the two electrodes adjacent to each other in the plane direction. As a result, there is a problem that the two electrodes are short-circuited, and reliability is lowered.

The present invention provides a connecting structure achieving a small size and a low height and having excellent reliability.

### Means for Solving the Problem

The present invention [1] includes a connecting structure including a first substrate having a plurality of first electrodes arranged in a plane direction: a second substrate having a plurality of second electrodes arranged in the plane direction and disposed at a spaced interval in a thickness direction perpendicular to the plane direction so that the first electrode faces the second electrode; and an adhesive layer interposed between the first substrate and the second substrate, electrically connecting the first electrode and the second electrode facing each other in the thickness direction, and adhering the first substrate to the second substrate, wherein a thickness of the adhesive layer is below 15 μm, and a distance between the first electrodes adjacent to each other in the plane direction is longer than the distance between the first electrode and the second electrode facing each other in the thickness direction.

The present invention [2] includes the connecting structure described in the above-described [1], wherein the adhesive layer is a cured product of an anisotropic electrically conductive adhesive film, and the anisotropic electrically conductive adhesive film includes a columnar solder portion electrically connecting the first electrode and the second electrode facing each other in the thickness direction, and a cured resin.

The present invention [3] includes the connecting structure described in the above-described [1] or [2], wherein the plurality of first electrodes and the plurality of second electrodes each are disposed as a dot pattern.

The present invention [4] includes the connecting structure described in the above-described [2], wherein the anisotropic electrically conductive adhesive film includes a solder particle and an average value of the maximum length of the solder particle is 3 μm or less.

The present invention [5] includes the connecting structure described in the above-described [2], wherein the anisotropic electrically conductive adhesive film includes a solder particle and an average value of the maximum length of the solder particle is 2 μm or less.

The present invention [6] includes the connecting structure described in the above-described [2], wherein the anisotropic electrically conductive adhesive film includes a solder particle and an average value of the maximum length of the solder particle is 1 μm or less.

The present invention [7] includes the connecting structure described in the above-described [2], wherein the anisotropic electrically conductive adhesive film includes a solder particle and the maximum length of the solder particle is 5 μm or less.

The present invention [8] includes the connecting structure described in the above-described [2], wherein the anisotropic electrically conductive adhesive film includes a solder particle and the maximum length of the solder particle is 3 μm or less.

### Effect of the Invention

In the connecting structure of the present invention, since the thickness of the adhesive layer is as thin as below 15 μm, it is possible to achieve a low height. Moreover, the distance between the first electrodes adjacent to each other in the plane direction is longer than the distance between the first electrode and the second electrode facing each other in the thickness direction. Therefore, it is possible to reliably electrically connect the first electrode and the second electrode facing each other in the thickness direction, while suppressing an electrical connection of the two first electrodes adjacent to each other in the plane direction. Therefore, it has excellent reliability.

### BRIEF DESCRIPTION OF THE DRAWINGS

FIG. 1 shows a cross-sectional view of one embodiment of a connecting structure of the present invention.

FIGS. 2A to 2E show one embodiment of a method for producing a connecting structure: FIG. 2A illustrating a first step of preparing a first substrate and a second substrate,

FIG. 2B illustrating a second step of preparing an anisotropic electrically conductive adhesive film.

FIG. 2C illustrating a third step of laminating a first substrate, an anisotropic electrically conductive adhesive film, and a second substrate,

FIG. 2D illustrating a fourth step of thermo-compressively bonding the first substrate and the second substrate to the anisotropic electrically conductive adhesive film, and

FIG. 2E illustrating a fifth step of forming an adhesive layer solder-bonding the first substrate and the second substrate to the anisotropic electrically conductive adhesive film.

FIG. 3 shows a plan view of a first substate.

FIG. 4 shows a plan view of a second substrate.

FIGS. 5A to SC show schematic views of a columnar solder portion in an adhesive layer:

FIG. 5A illustrating an embodiment in which when a distance between first electrodes adjacent to each other in a plane direction is longer than the distance between the first electrode and a second electrode facing each other in a thickness direction, the first electrode and the second electrode facing each other in the thickness direction are electrically connected, while suppressing an electrical connection between the two first electrodes adjacent to each other;

FIG. 5B illustrating an embodiment in which when the distance between the first electrodes adjacent to each other in the plane direction is shorter than the distance between the first electrode and the second electrode facing each other in the thickness direction, the columnar solder portions adjacent to each other in the plane direction are electrically connected, while electrically connecting the first electrode and the second electrode facing each other in the thickness direction; and

FIG. 5C illustrating an embodiment in which when the distance between the first electrodes adjacent to each other in the plane direction is shorter than the distance between the first electrode and the second electrode facing each other in the thickness direction, the two first electrodes adjacent to each other are electrically connected without electrically connecting the first electrode and the second electrode facing each other in the thickness direction.

### DESCRIPTION OF EMBODIMENTS

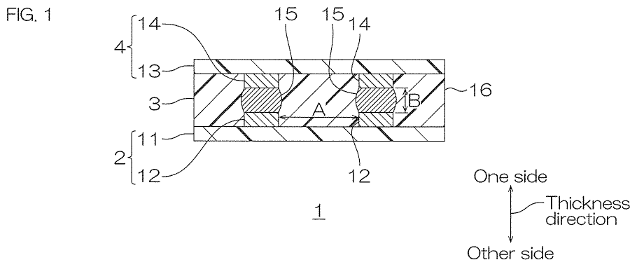

One embodiment of a connecting structure of the present invention is described in detail with reference to FIG. 1.

In FIG. 1, an up-down direction on the plane of the sheet is referred to as the up-down direction (thickness direction). Further, an upper side on the plane of the sheet is referred to as the upper side (one side in the thickness direction), and a lower side on the plane of the sheet is referred to as the lower side (the other side in the thickness direction). Further, a right-left direction on the plane of the sheet and a depth direction are a plane direction perpendicular to the up-down direction. Specifically, directions are in conformity with direction arrows of each view.

As shown in FIG. 1, a connecting structure 1 includes a first substrate 2, a second substrate 4 disposed at a spaced interval in the thickness direction, and an adhesive layer 3 interposed between the first substrate 2 and the second substrate 4. In other words, the connecting structure 1 includes the first substrate 2, the adhesive layer 3, and the second substrate 4 in order toward one side in the thickness direction. More specifically, the connecting structure 1 includes the first substrate 2, the adhesive layer 3 which is directly disposed on the upper surface (one surface in the thickness direction) of the first substrate 2, and the second substrate 4 which is directly disposed on the upper surface (one surface in the thickness direction) of the adhesive layer 3.

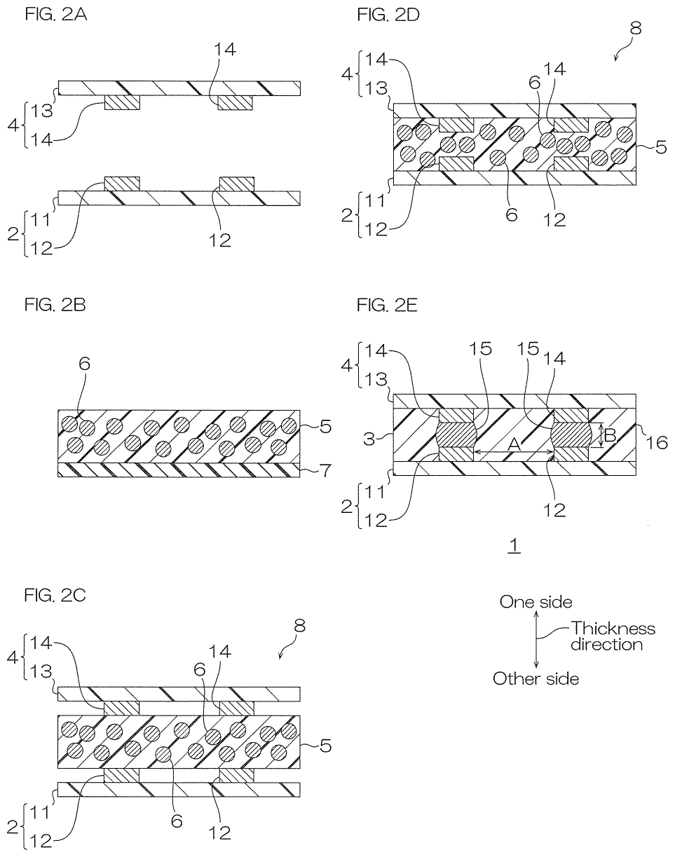

In the following, a method for producing the connecting structure 1 is described in detail with reference to FIGS. 2A to 2E. Although the details are described later, in this method, the connecting structure 1 is produced using an anisotropic electrically conductive adhesive film. That is, the adhesive layer 3 in the connecting structure 1 obtained by this method is a cured product of the anisotropic electrically conductive adhesive film.

### <Method for Producing Connecting Structure>

The method for producing a connecting structure includes a first step of preparing the first substrate 2 and the second substrate 4: a second step of preparing an anisotropic electrically conductive adhesive film 5: a third step of laminating the first substrate 2, the anisotropic electrically conductive adhesive film 5, and the second substrate 4: a fourth step of thermo-compressively bonding the first substrate 2 and the second substrate 4 to the anisotropic electrically conductive adhesive film 5; and a fifth step of forming the adhesive layer 3 solder-bonding the first substrate 2 and the second substrate 4 to the anisotropic electrically conductive adhesive film 5.

### [First Step]

In the first step, as shown in FIG. 2A, the first substrate 2 and the second substrate 4 are prepared.

The first substrate 2 has a flat plate shape.

The first substrate 2 includes a first wiring circuit board 11, and a plurality of first electrodes 12 arranged in the plane direction of the first wiring circuit board 11. In other words, the first substrate 2 includes the first wiring circuit board 11, and the plurality of first electrodes 12 provided on the surface (one surface in the thickness direction) of the first wiring circuit board 11.

The first wiring circuit board 11 is formed of an insulating material.

A thickness of the first wiring circuit board 11 is, for example, 5 μm or more, and for example, 1000 μm or less.

The first electrode 12 is made of a metal.

As referred to a plan view of the first substrate 2 shown in FIG. 3, the first electrodes 12 are disposed as a dot pattern in the first substrate 2.

Specifically, the first electrode 12 has a circular shape when viewed from the top. Further, the plurality of first electrodes 12 are evenly disposed in alignment in the plane direction.

When the first electrodes 12 are disposed as the dot pattern, it is possible to reliably electrically connect the first electrode 12 and a second electrode 14 facing each other in the thickness direction, while suppressing an electrical connection of the two first electrodes 12 adjacent to each other in the plane direction. As a result, it is possible to improve reliability.

The thickness of the first electrode 12 is, for example, 0 μm or more, preferably 0.001 μm or more, and for example, 5 μm or less. In a case where the surface of the first substrate 2 and the surface of the first electrode 12 are matched, the thickness of the first electrode 12 is 0 μm.

Further, a distance (pitch) of the first electrodes 12 adjacent to each other in the plane direction is, for example, 3 μm or more, preferably 5 μm or more, and for example, 500 μm or less, preferably 100 μm or less.

Further, the above-described distance (pitch) is the same as a distance A between the first electrodes 12 adjacent to each other in the plane direction (described later).

Further, though the details are described later, the distance (pitch) between the first electrodes 12 adjacent to each other in the plane direction (the distance A between the first electrodes 12 adjacent to each other in the plane direction) is longer than a distance B between the first electrode 12 and the second electrode 14 facing each other in the thickness direction.

The second substrate 4 has the flat plate shape.

The second substrate 4 includes a second wiring circuit board 13, and the plurality of second electrodes 14 arranged in the plane direction of the second wiring circuit board 13. In other words, the second substrate 4 includes the second wiring circuit board 13, and the plurality of second electrodes 14 provided on the surface (the other surface in the thickness direction) of the second wiring circuit board 13.

The second wiring circuit board 13 is, for example, formed of an insulating material and a semiconductor material.

The thickness of the second wiring circuit board 13 is, for example, 5 μm or more, and for example, 1000 μm or less.

The second electrode 14 is made of the metal.

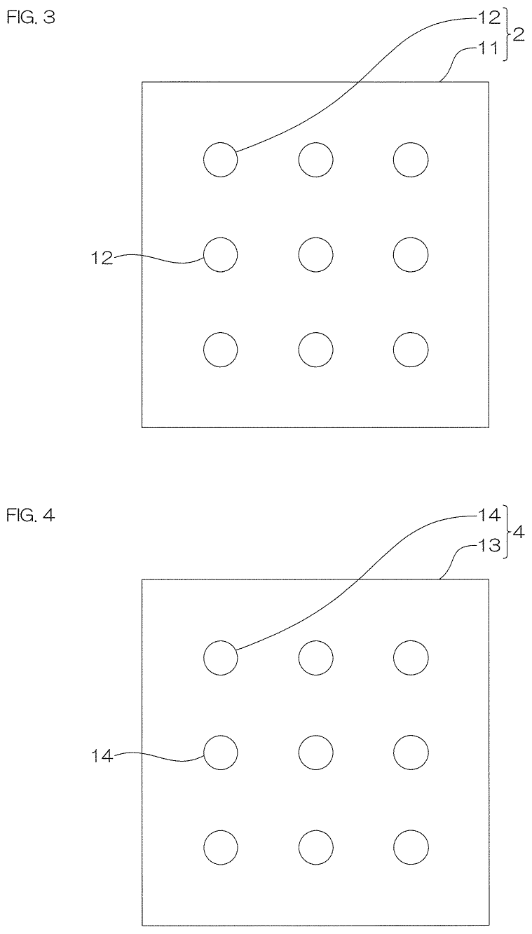

As referred to the plan view of the second substrate 4 shown in FIG. 4, the second electrodes 14 are disposed as the dot pattern in the second substrate 4.

Specifically, the second electrode 14 has the circular shape when viewed from the top. Further, the plurality of second electrodes 14 are evenly disposed in alignment in the plane direction.

When the second electrodes 14 are disposed as the dot pattern, it is possible to reliably electrically connect the first electrode 12 and the second electrode 14 facing each other in the thickness direction, while suppressing the electrical connection of the two first electrodes 12 adjacent to each other in the plane direction. As a result, it is possible to improve the reliability.

The thickness of the second electrode 14 is, for example, 0 μm or more, preferably 0.001 μm or more, and for example, 5 μm or less. In a case where the surface of the second substrate 4 and the surface of the second electrode 14 are matched, the thickness of the second electrode 14 is 0 μm.

Further, the distance (pitch) of the second electrodes 14 adjacent to each other in the plane direction is the same as the distance (pitch) of the first electrodes 12 adjacent to each other in the above-described plane direction.

### [Second Step]

In the second step, as shown in FIG. 2B, the anisotropic electrically conductive adhesive film 5 is prepared.

In order to prepare the anisotropic electrically conductive adhesive film 5, first, an anisotropic electrically conductive adhesive film composition is prepared.

The anisotropic electrically conductive adhesive film composition contains solder particles 6 and a curable resin.

An example of the solder material which forms the solder particles 6 includes, from the viewpoint of environmental adequacy, the solder material which does not contain the lead (lead-free solder material). Specifically, examples of the solder material include tin and tin alloys. Examples of the tin alloy include tin-bismuth alloys (Sn—Bi), tin-silver-copper alloys (Sn—Ag—Cu), and tin-silver alloys (Sn—Ag). As the solder material, preferably, a tin-silver-copper alloy (Sn—Ag—Cu) and a tin-silver alloy (Sn—Ag) are used.

A content ratio of the tin in the tin-bismuth alloy is, for example, 10% by mass or more, preferably 25% by mass or more, and for example, 50% by mass or less, preferably 45% by mass or less. Further, the content ratio of the bismuth in the tin-bismuth alloy is, for example, 50% by mass or more, preferably 55% by mass or more, and for example, 90% by mass or less, preferably 75% by mass or less.

Further, the content ratio of the tin in the tin-silver-copper alloy is, for example, 90% by mass or more, preferably 95% by mass or more. Further, the content ratio of the silver in the tin-silver-copper alloy is, for example, 10% by mass or less, preferably 5% by mass or less. Further, the content ratio of the copper in the tin-silver-copper alloy is, for example, 1% by mass or less, preferably 0.5% by mass or less.

Further, the content ratio of the tin in the tin-silver alloy is, for example, 90% by mass or more, preferably 95% by mass or more. Further, the content ratio of the silver in the tin-silver alloy is, for example, 10% by mass or less, preferably 5% by mass or less.

A melting point of the solder material (that is, the melting point of the solder particles 6) is, for example, 260° C. or less, preferably 235° C. or less, and for example, 100° C. or more, preferably 130° C. or more. The melting point is determined by differential scanning calorimetry (DSC) (hereinafter, the same applies).

A shape of the solder particle 6 is not particularly limited, and examples of the shape thereof include spherical shapes, plate shapes, and needle shapes. As the shape of the solder particle 6, preferably, a spherical shape is used. In FIG. 2B, the shape of the solder particle 6 is shown as the spherical shape, and the shape of the solder particle 6 is not limited to this.

An average value of the maximum length of the solder particle 6 (in the case of the spherical shape, an average particle size D₅₀) is, for example, below 15 μm, preferably 10 μm or less, more preferably 5 μm or less, further more preferably, from the viewpoint of achieving a small size and a low height, 3 μm or less, particularly preferably 2 μm or less, most preferably 1 μm or less. The average value of the maximum length is measured using a laser diffraction scattering particle size distributer. Further, the average value of the maximum length can be adjusted by classification.

Further, the maximum length of the solder particle 6 (in the case of the spherical shape, a maximum particle size Dₘₐₓ) is, for example, 20 μm or less, preferably 10 μm or less, more preferably, from the viewpoint of achieving the small size and the low height, 5 μm or less, further more preferably 3 μm or less. The maximum length is measured using the laser diffraction scattering particle size distributer. Further, the average value of the maximum length can be adjusted by classification.

The surface of the solder particle 6 is generally covered with an oxide film made of an oxide of the solder material. The thickness of the oxide film is, for example, 1 nm or more, and for example, 20 nm or less.

The content ratio of the solder particle 6 is, for example, 10% by volume or more, preferably 15% by volume or more, and for example, 50% by volume or less, preferably 40% by volume or less with respect to the anisotropic electrically conductive adhesive film composition.

These solder particles 6 may be used alone or in combination of two or more.

Examples of the curable resin include thermosetting resins. Examples of the thermosetting resin include epoxy resins (for example, bisphenol A-type epoxy resins), urea resins, melamine resins, diallyl phthalate resins, silicone resins, phenol resins, thermosetting acrylic resins, thermosetting polyesters, thermosetting polyimides, and thermosetting polyurethanes. As the curable resin, preferably, an epoxy resin is used.

The curable resin is liquid at 25° C. or solid at 25° C.

In a case where the curable resin is solid at 25° C., a softening point of the curable resin is, for example, 50° C. or more, preferably 80° C. or more, and for example, 230° C. or less, preferably 200° C. or less. The softening point can be measured with a thermomechanical analyzer.

The content ratio of the curable resin is, for example, 10% by volume or more, preferably 20% by volume or more, and for example. 90% by volume or less, preferably 85% by volume or less with respect to the anisotropic electrically conductive adhesive film composition.

These curable resins may be used alone or in combination of two or more.

The anisotropic electrically conductive adhesive film composition may also contain a thermoplastic resin as needed.

The thermoplastic resin is blended in order to reliably mold the anisotropic electrically conductive adhesive film composition into a sheet shape. Examples of the thermoplastic resin include phenoxy resins, polyolefins (for example, polyethylene, polypropylene, ethylene-propylene copolymer, etc.), acrylic resins, polyesters, polyvinyl acetate, ethylene-vinyl acetate copolymers, polyvinyl chloride, polystyrene, polyacrylonitrile, polyamide (nylon (registered trademark)), polycarbonate, polyacetal, polyethylene terephthalate, polyphenylene oxide, polyphenylene sulfide, polysulfone, polyether sulfone, polyether ether ketone, poly allyl sulfone, thermoplastic polyimide, thermoplastic polyurethane, polyaminobismaleimide, polyamide imide, polyether imide, bismaleimide triazine resins, polymethyl pentene, fluoride resins, liquid crystal polymers, olefin-vinyl alcohol copolymers, ionomers, polyarylate, acrylonitrile-ethylene-styrene copolymers, acrylonitrile-butadiene-styrene copolymers, acrylonitrile-styrene copolymers, and butadiene-styrene copolymers. As the thermoplastic resin, preferably, an acrylic resin and a phenoxy resin are used.

The content ratio of the thermoplastic resin is, for example, 5% by volume or more, preferably 10% by volume or more, and for example, 80% by volume or less, preferably 70% by volume or less with respect to the anisotropic electrically conductive adhesive film composition.

These thermoplastic resins may be used alone or in combination of two or more.

Further, the anisotropic electrically conductive adhesive film composition may also include flux as needed.

The flux is a component for removing the oxide film (oxide film made of the oxide of the solder material) on the surface of the solder particle 6.

Examples of a material for the flux include organic acid salts. Examples of the organic acid salt include organic acids, quinolinol derivatives, and metal carbonyl acid salts. Examples of the organic acid include aliphatic carboxylic acids and aromatic carboxylic acids. Examples of the aliphatic carboxylic acid include aliphatic dicarboxylic acids. Specifically, examples of the aliphatic dicarboxylic acid include adipic acid, malic acid, malonic acid, succinic acid, glutaric acid, pimelic acid, suberic acid, and sebacic acid. Examples of the aromatic carboxylic acid include benzoic acid, 2-phenoxybenzoic acid, phthalic acid, diphenylacetic acid, trimellitic acid, and pyromellitic acid. As the material for the flux, preferably, an organic acid is used. As the material for the flux, more preferably, a malic acid is used.

The melting point of the flux is, for example, 250° C. or less, preferably 180° C. or less, more preferably 160° C. or less, and for example, 100° C. or more, preferably 120° C. or more, more preferably 130° C. or more.

The shape of the flux is not particularly limited, and examples of the shape thereof include plate shapes, needle shapes, and spherical shapes. Further, the flux may be also dissolved in a known solvent.

The content ratio of the flux is, for example, 0.1% by volume or more, preferably 1% by volume or more, and for example, 50% by volume or less, preferably 20% by volume or less with respect to the anisotropic electrically conductive adhesive film composition.

The flux may be used alone or in combination of two or more.

Further, the anisotropic electrically conductive adhesive film composition may also contain an additive (for example, a curing agent, a curing accelerator, and a silane coupling agent) as needed.

Then, in order to prepare the anisotropic electrically conductive adhesive film composition, the solder particles 6, the curable resin, the thermoplastic resin to be blended as needed, the flux to be blended as needed, and the additive to be blended as needed are mixed. Thus, the anisotropic electrically conductive adhesive film composition is prepared. Further, the anisotropic electrically conductive adhesive film composition can be blended into a known solvent, thereby preparing the anisotropic electrically conductive adhesive film composition as a varnish.

Next, in order to prepare the anisotropic electrically conductive adhesive film 5, an anisotropic electrically conductive adhesive film composition (varnish of the anisotropic electrically conductive adhesive film composition) is coated onto one surface in the thickness direction of a release liner 7, and thereafter, the coated surface is dried as needed.

The release liner 7 is a film for covering and protecting the anisotropic electrically conductive adhesive film 5. The release liner 7 has a film shape.

The release liner 7 is, for example, a plastic substrate (plastic film). Examples of the plastic substrate include polyester sheets (polyethylene terephthalate (PET) sheet), polyolefin sheets (for example, polyethylene sheet and polypropylene sheet), polyvinyl chloride sheets, polyimide sheets, and polyamide sheets (nylon sheet). The surface (one surface in the thickness direction) of the release liner 7 may be also subjected to a surface treatment such as silicone treatment.

The thickness of the release liner 7 is, for example, 1 μm or more, and for example, 100 μm or less.

As drying conditions, a drying temperature is, for example, 40° C. or more, and for example, 100° C. or less. The drying time is, for example, 1 minute or more, and for example, 60 minutes or less.

Thus, the anisotropic electrically conductive adhesive film 5 is prepared on one surface in the thickness direction of the release liner 7.

Such an anisotropic electrically conductive adhesive film 5 has a film shape having a predetermined thickness (including a sheet shape).

The anisotropic electrically conductive adhesive film 5 is formed from the anisotropic electrically conductive adhesive film composition including the solder particles 6 and the curable resin. Therefore, the anisotropic electrically conductive adhesive film 5 includes the solder particles 6 and the curable resin. Specifically, the anisotropic electrically conductive adhesive film 5 includes the curable resin and the solder particles 6 dispersed in the curable resin.

The thickness of the anisotropic electrically conductive adhesive film 5 is, from the viewpoint of achieving the low height, for example, below 15 μm, preferably 10 μm or less, more preferably below 10 μm, further more preferably 5 μm or less, and for example, 1 μm or more.

Thus, the anisotropic electrically conductive adhesive film 5 is prepared.

### [Third Step]

In the third step, as shown in FIG. 2C, the first substrate 2, the anisotropic electrically conductive adhesive film 5, and the second substrate 4 are laminated.

Specifically, the first substrate 2 and the second substrate 4 are brought into closer contact with the anisotropic electrically conductive adhesive film 5, and the first substrate 2 and the second substrate 4 are brought into contact with the anisotropic electrically conductive adhesive film 5. More specifically, one surface in the thickness direction of the first substrate 2 is brought into contact with the other surface in the thickness direction of the anisotropic electrically conductive adhesive film 5, and one surface in the thickness direction of the second substrate 4 is brought into contact with one surface in the thickness direction of the anisotropic electrically conductive adhesive film 5 so that the first electrode 12 and the second electrode 14 face each other in the thickness direction.

Thus, the first substrate 2, the anisotropic electrically conductive adhesive film 5, and the second substrate 4 are laminated, thereby producing a laminate 8.

### [Fourth Step]

In the fourth step, as shown in FIG. 2D, the first substrate 2 and the second substrate 4, and the anisotropic electrically conductive adhesive film 5 are thermo-compressively bonded to each other.

Specifically, the first substrate 2 and the second substrate 4 are pressed (thermo-compressively bonded) toward the anisotropic electrically conductive adhesive film 5, while the laminate 8 is heated.

A temperature of the thermocompression bonding is the temperature which is below the melting point of the solder particles 6. Specifically, the temperature of the thermocompression bonding is, for example, below 100° C., preferably 80° C. or less, and for example, 40° C. or more, preferably 60° C. or more. Further, the pressure of the thermocompression bonding is, for example, 0.001 MPa or more, preferably 0.005 MPa or more, more preferably 0.01 MPa or more, and for example, 10 MPa or less, preferably 5 MPa or less, more preferably 1 MPa or less.

Thus, one surface in the thickness direction of the first substrate 2 is covered with the anisotropic electrically conductive adhesive film 5, while the first electrode 12 of the first substrate 2 is embedded in the anisotropic electrically conductive adhesive film 5. Further, the other surface in the thickness direction of the second substrate 4 is covered with the anisotropic electrically conductive adhesive film 5, while the second electrode 14 of the second substrate 4 is embedded in the anisotropic electrically conductive adhesive film 5.

### [Fifth Step]

In the fifth step, as shown in FIG. 2E, the adhesive layer 3 which solder-bonds the first substrate 2 and the second substrate 4 to the anisotropic electrically conductive adhesive film 5 is formed.

Specifically, the laminate 8 is heated.

A heating temperature is the temperature which is the melting point or more of the solder particles 6. Specifically, the heating temperature is, for example, 100° C. or more, preferably 130° C. or more, more preferably 200° C. or more, and for example, 400° C. or less, preferably 350° C. or less, more preferably 300° C. or less.

The solder particles 6 are melted by such heating. The melted solder particles 6 aggregate (self-aggregate) between the first electrode 12 and the second electrode 14 facing each other in the thickness direction, thereby forming a columnar solder portion 15. On the other hand, the curable resin in the anisotropic electrically conductive adhesive film 5 is forced out by the self-aggregating solder particles 6, and moves to the periphery of the columnar solder portion 15. Thereafter, the curable resin is thermally cured to become a cured resin 16 which adheres the first substrate 2 to the second substrate 4.

As described above, most of the melted solder particles 6 are used for the formation of the columnar solder portion 15, and a portion of the melted solder particles 6 and/or the non-melted solder particles 6 are/is not used for the formation of the columnar solder portion 15. There is a case where they remain dispersed in the curable resin. In such a case, the cured resin 16 includes a portion of the melted solder particles 6 and/or the non-melted solder particles 6.

Thus, the adhesive layer 3 including the columnar solder portion 15 and the cured resin 16 is formed.

The thickness of the adhesive layer 3 is, from the viewpoint of achieving the low height, below 15 μm, preferably 10 μm or less, more preferably below 10 μm, further more preferably 5 μm or less, and for example, 1 μm or more,

As described above, the connecting structure 1 is produced.

### <Connecting Structure>

As shown in FIG. 2E, the connecting structure 1 includes the first substrate 2, the second substrate 4 disposed at a spaced interval in the thickness direction so that the first electrode 12 and the second electrode 14 face each other, and the adhesive layer 3 interposed between the first substrate 2 and the second substrate 4.

The adhesive layer 3 includes the columnar solder portion 15 and the cured resin 16.

The adhesive layer 3 adheres the first substrate 2 to the second substrate 4. Specifically, the adhesive layer 3 adheres to the surface of the first substrate 2 except for the first electrode 12. Further, the adhesive layer 3 adheres to the surface of the second substrate 4 except for the second electrode 14.

Further, the columnar solder portion 15 electrically connects the first electrode 12 and the second electrode 14 facing each other in the thickness direction. Further, the columnar solder portion 15 has a columnar shape (specifically, cylindrical shape), and is disposed between the first electrode 12 and the second electrode 14 to be in contact therewith.

The thickness (height) of the columnar solder portion 15 is, for example, 1 μm or more, preferably 3 μm or more, and for example, 10 μm or less, preferably 5 μm or less.

Further, the thickness of the columnar solder portion 15 is the same as the distance B (described later) between the first electrode 12 and the second electrode 14 facing each other in the thickness direction.

Also, the thickness of the adhesive layer 3 is the same as the total sum of the thickness of the first electrode 12, the thickness of the second electrode 14, and the thickness of the columnar solder portion 15.

Then, in the connecting structure 1, the distance A between the first electrodes 12 adjacent to each other in the plane direction (hereinafter, may be referred to as the distance A) is longer than the distance B between the first electrode 12 and the second electrode 14 facing each other in the thickness direction (hereinafter, may be referred to as the distance B).

In other words, the distance A and the distance B satisfy the following formula (1):

A>B (1)

Thus, it is possible to reliably electrically connect the first electrode 12 and the second electrode 14 facing each other in the thickness direction, while suppressing the electrical connection of the two first electrodes 12 adjacent to each other. As a result, it is possible to improve the reliability.

Specifically, the distance A is the same as the distance (pitch) of the first electrodes 12 adjacent to each other in the above-described plane direction. Specifically, the distance A is 3 μm or more, preferably 5 μm or more, and for example, 500 μm or less, preferably 100 μm or less.

Further, the distance B is the same as the thickness of the above-described columnar solder portion 15. Specifically, the distance B is 1 μm or more, preferably 3 μm or more, and for example, 10 μm or less, preferably 5 μm or less.

A difference between the distance A and the distance B (distance A-distance B) is, for example. 1 μm or more, preferably 5 μm or more, and for example, 499 μm or less, preferably 100 μm or less.

A ratio (distance B/distance A) of the distance B to the distance A is, for example, 0.01 or more, preferably 0.1 or more, and for example, below 1, preferably 0.8 or less.

The thickness of the connecting structure 1 is, for example, 50 μm or more, and for example, 1000 μm or less.

### <Function and Effect>

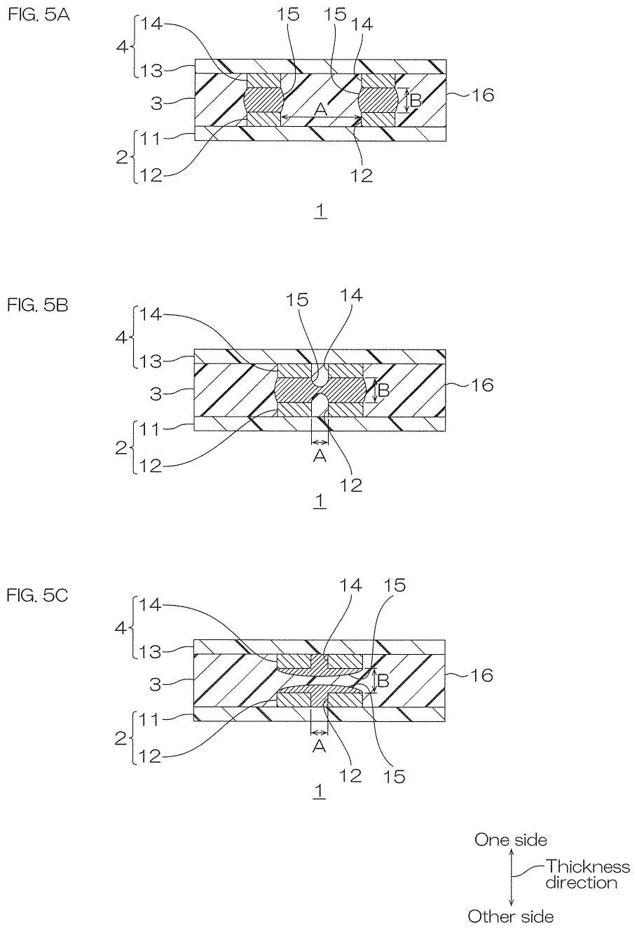

In the connecting structure 1, the thickness of the adhesive layer 3 is as thin as below 15 μm. Therefore, it is possible to achieve the low height. Further, in the connecting structure 1, the distance A is longer than the distance B. That is, in the connecting structure 1, the distance A and the distance B satisfy the above-described formula (1). Thus, as shown in FIG. 5A, it is possible to reliably electrically connect the first electrode 12 and the second electrode 14 facing each other in the thickness direction, while suppressing the electrical connection of the two first electrodes 12 adjacent to each other. As a result, it is possible to improve the reliability.

On the other hand, in the connecting structure 1, when the distance A and the distance B do not satisfy the above-described formula (1), in other words, when the distance A and the distance B satisfy the following formula (2), as shown in FIG. 5B, the columnar solder portions 15 adjacent to each other in the plane direction are electrically connected, while the first electrode 12 and the second electrode 14 facing each other in the thickness direction are electrically connected (that is, the two first electrodes 12 adjacent to each other are electrically connected). Or, as shown in FIG. 5C, the two first electrodes 12 adjacent to each other are electrically connected without electrically connecting the first electrode 12 and the second electrode 14 facing each other in the thickness direction. In either case, since the two first electrodes 12 adjacent to each other are electrically connected, the two first electrodes 12 are short-circuited, thereby lowering the reliability.

A≤B (2)

Above all, from the viewpoint of high density of a circuit (narrowing pitch of the electrode), the distance A tends to be shorter than the distance B.

On the other hand, in the connecting structure 1, by thinning the thickness of the adhesive layer 3 (specifically, below 15 μm), it is possible to make the distance A longer than the distance B, and as a result, it is possible to improve the reliability.

### Modified Examples

In each modified example below, the same reference numerals are provided for members and steps corresponding to each of those in one embodiment, and their detailed description is omitted. Further, each modified example can achieve the same function and effect as that of one embodiment unless otherwise specified. Furthermore, one embodiment and each modified example can be appropriately used in combination.

In the above-described description, the adhesive layer 3 is the cured product of the anisotropic electrically conductive adhesive film. However, the adhesive layer 3 is not particularly limited as long as it is a layer which electrically connects the first electrode 12 to the second electrode 14, and adheres the first substrate 2 to the second substrate 4, and may be, for example, the cured product of anisotropic electrically conductive adhesive paste.

The anisotropic electrically conductive adhesive paste includes, for example, the above-described solder particles 6, the above-described curable resin, and an activator (for example, carboxylic acid).

Even when the anisotropic electrically conductive adhesive paste is used, in the same manner as the above-described fifth step, the columnar solder portion 15 which electrically connects the first electrode 12 to the second electrode 14 is formed, and the curable resin is cured to become the cured resin 16, so that the first substrate 2 adheres to the second substrate 4.

Further, in the above-described description, the first electrodes 12 and the second electrodes 14 are disposed as the dot pattern. However, the arrangement of the first electrodes 12 and the second electrodes 14 is not limited to this.

Further, in the above-described description, the first electrode 12 and the second electrode 14 have the circular shape when viewed from the top, and the shape of the first electrode 12 and the second electrode 14 is not limited to this. For example, it may also have a rectangular shape when viewed from the top.

Further, in the above-described description, the second substrate 4 has a flat plate shape. However, the shape of the second substrate 4 is not limited to this. For example, it may also have a shape having a tip component (for example, mini/microLED).

Further, in the above-described description, in the third step, the first substrate 2 and the second substrate 4 are brought into closer contact with the anisotropic electrically conductive adhesive film 5, and the first substrate 2 and the second substrate 4 are brought into contact with the anisotropic electrically conductive adhesive film 5. Alternatively, first, the anisotropic electrically conductive adhesive film 5 may be disposed on one surface in the thickness direction of the first substrate 2 (surface on which the first electrode 12 is provided), and next, the second substrate 4 may be also disposed on one surface in the thickness direction of the anisotropic electrically conductive adhesive film 5 so that the first electrode 12 and the second electrode 14 face each other. Further, one surface in the thickness direction of the anisotropic electrically conductive adhesive film 5 may be also subjected to a surface treatment (for example, surface treatment by applying a silica filler) before the second substrate 4 is disposed.

Further, in the above-described description, the fourth step and the fifth step are carried out as separate steps. Alternatively, it is also possible to carry out the fourth step and the fifth step simultaneously. In such a case, the thermocompression bonding is carried out at the pressure in the fourth step and the temperature in the fifth step.

Further, in the above-described description, in the fourth step, the first substrate 2, the second substrate 4, and the anisotropic electrically conductive adhesive film 5 are thermo-compressively bonded. Among all, when the second substrate 4 is the chip component, it is also possible to produce the connecting structure 1 by reflow or vacuum reflow without carrying out the thermocompression bonding.

### EXAMPLES

Next, the present invention is further described based on Examples and Comparative Examples. The present invention is however not limited by Examples below. Further, all designations of “part” or “parts” and “%” mean part or parts by mass and % by mass, respectively, unless otherwise particularly specified in the following description. The specific numerical values in mixing ratio (content ratio), property value, and parameter used in the following description can be replaced with upper limit values (numerical values defined as “or less” or “below”) or lower limit values (numerical values defined as “or more” or “above”) of corresponding numerical values in mixing ratio (content ratio), property value, and parameter described in the above-described “DESCRIPTION OF EMBODIMENTS”.

### <Details of Components>

Trade names and abbreviations of each of the components used in Examples and Comparative Examples are described in detail.

jER828: bisphenol A-type epoxy resin, epoxy equivalent of 184 to 194 g/eq, liquid at room temperature (25° C.), manufactured by Mitsubishi Chemical Corporation

ARUFON UH-2170: acrylic resin (hydroxyl group-containing styrene acrylic polymer), solid at room temperature (25° C.′), manufactured by TOAGOSEI CO., LTD.

Solder particle A: (alloy of 96.5% by mass of Sn and 3.5% by mass of Ag, melting point of 221° C., spherical shape, particle size D₅₀ of 3 μm, maximum particle size Dₘₐₓ of 12 μm, oxygen concentration of 1100 ppm)

Solder particle B: solder particle obtained by classifying the solder particle (alloy of 96.5% by mass of Sn. 3.0% by mass of Ag, and 0.5% by mass of Cu, melting point of 217 to 219° C. spherical shape, particle size D₅₀ of 3 μm, oxygen concentration of 1100 ppm), particle size D₅₀ of 2 μm, maximum particle size Dₘₐₓ of 4.6 μm

Solder particle C: solder particle obtained by classifying the solder particle (alloy of 96.5% by mass of Sn, 3.0% by mass of Ag, and 0.5% by mass of Cu, melting point of 217 to 219° C., spherical shape, particle size D₅₀ of 3 μm, oxygen concentration of 1100 ppm), particle size D₅₀ of 1 μm, maximum particle size Dₘₐₓ of 2.9 μm

### <Production of Connecting Structure>

### Example 1

### [First Step]

The first substrate was prepared. The first substrate had the cylindrical first electrode having a diameter of 15 μm and a thickness of 1 μm, and the distance A between the first electrodes adjacent to each other was 15 μm.

Separately, the second substrate was prepared. The second substrate had the cylindrical second electrode having the diameter of 15 μm and the thickness of 1 μm, and the distance between the second electrodes adjacent to each other was 15 μm.

### [Second Step]

The anisotropic electrically conductive adhesive film was prepared. Specifically, first, 50 parts by mass of jER828 as the thermosetting resin, 50 parts by mass of ARUFON UH-2170 as the thermoplastic resin, 150 parts by mass of solder particles A, and 20 parts by mass of malic acid as a flux agent were added to methyl ethyl ketone (MEK) to be mixed. Thus, the anisotropic electrically conductive adhesive film composition (solid concentration of 50% by mass) was prepared.

Next, the anisotropic electrically conductive adhesive film composition was coated onto a release liner, thereby forming a coating film. Thereafter, the coating film was dried at 80° C. for 5 minutes. Thus, the anisotropic electrically conductive adhesive film was prepared.

### [Third Step]

The first substrate, the anisotropic electrically conductive adhesive film, and the second substrate were laminated. Specifically, the anisotropic electrically conductive adhesive film was transferred to one surface in the thickness direction of the first substrate (surface on which the first electrode was provided). Next, a silica filler having a diameter φS=5 μm (trade name: “HIPRESICA”, manufactured by UBE EXSYMO CO., LTD.) was coated onto one surface in the thickness direction of the anisotropic electrically conductive adhesive film. After removing the excessive silica filler with an air blower, the second substrate was disposed so that the first electrode and the second electrode faced each other. Thus, a laminate including the first substrate, the anisotropic electrically conductive adhesive film, and the second substrate in order in the thickness direction was produced.

### [Fourth Step and Fifth Step]

The laminate was heated at 260° C. for one minute, while 10 kPa of pressure was applied thereto in the thickness direction. Thus, the columnar solder portion and the cured resin were formed, thereby producing a connecting structure. The distance B between the first electrode and the second electrode facing each other in the thickness direction which was measured with a microscope was 7 μm.

### Examples 2 to 7 and Comparative Examples 1 to 4

A connecting structure was produced based on the same procedure as in Example 1. However, the formulation of the anisotropic electrically conductive adhesive film composition and the thickness of the anisotropic electrically conductive adhesive film were changed in accordance with Table 1. In Example 3, in the third step, the silica filler having the diameter @S=10 μm was coated onto one surface in the thickness direction of the anisotropic electrically conductive adhesive film. Further, in Comparative Example 2, the silica filler having the diameter @S=15 μm was coated.

### <Evaluation>

### [Reliability]

### (Bridge Generation)

As for each of the connecting structures of Examples and Comparative Examples, a presence or absence of a bridge connecting between the first electrodes adjacent to each other was observed using an X-ray transmission observation device (SMX-100, manufactured by Shimadzu Corporation). The bridge generation was evaluated based on the following criteria. The results are shown in Table 1.

### [Criteria]

o: No bridge was observed.
x: A bridge was observed.

### (Electrical Conduction of Electrodes Facing Each Other)

As for each of the connecting structures of Examples and Comparative Examples, the connecting structure was polished up to a portion of the connection formation by using the anisotropic electrically conductive adhesive film, and a cross section of the connecting portion was ensured to be confirmed. Thereafter, the columnar solder portion was observed. As for the electrical conduction of the electrodes facing each other, evaluation was conducted based on the following criteria. The results are shown in Table 1.

### [Criteria]

O: Connection of the first electrode and the second electrode by the columnar solder portion was observed.
x: Connection of the first electrode and the second electrode by the columnar solder portion was not observed.

TABLE 1

| | | | | Ex.- Comparative Ex. No. | | | | | | | | | | |
|---|---|---|---|---|---|---|---|---|---|---|---|---|---|---|
| | | | | Ex. | Ex. | Comp. | Ex. | Comp. | Ex. | Ex. | Comp. | Ex. | Ex. | Comp. |
| | | | | 1 | 2 | Ex. 1 | 3 | Ex. 2 | 4 | 5 | Ex. 3 | 6 | 7 | Ex. 4 |
| Anisotropic | Thermosetting | jER828 | | 50 | 50 | 50 | 50 | 50 | 50 | 50 | 50 | 50 | 50 | 50 |
| Electrically | Resin | | | | | | | | | | | | | |
| Conductive | Thermoplastic | ARUFON UH-2170 | | 50 | 50 | 50 | 50 | 50 | 50 | 50 | 50 | 50 | 50 | 50 |
| Adhesive Film | Resin | | | | | | | | | | | | | |
| Composition | Solder | Solder | SnAg | 150 | 150 | 150 | 150 | 150 | — | — | — | — | — | — |
| | Particle | Particle A | | | | | | | | | | | | |
| | | Solder | SnAgCu | — | — | — | — | — | 150 | 150 | 150 | — | — | — |
| | | Particle B | | | | | | | | | | | | |
| | | Solder | SnAgCu | — | — | — | — | — | — | — | — | 150 | 150 | 150 |
| | | Particle C | | | | | | | | | | | | |

| | Flux Agent | Malic Acid | 20 | 20 | 20 | 20 | 20 | 20 | 20 | 20 | 20 | 20 | 20 |
|---|---|---|---|---|---|---|---|---|---|---|---|---|---|
| Thickness of Anisotropic Electrically | | | 5 | 10 | 15 | 10 | 15 | 5 | 10 | 15 | 5 | 10 | 15 |
| Conductive Adhesive Film (μm) | | | | | | | | | | | | | |
| Thickness of Adhesive Layer (μm) | | | 5 | 10 | 15 | 10 | 15 | 5 | 10 | 15 | 5 | 10 | 15 |
| Distance A between First Electrodes | | | 15 | 15 | 15 | 15 | 15 | 15 | 15 | 15 | 15 | 15 | 15 |
| Adjacent to Each Other (μm) | | | | | | | | | | | | | |
| Distance B between First Electrode and Second | | | 7 | 7 | 7 | 10 | 15 | 7 | 7 | 7 | 7 | 7 | 7 |
| Electrode Facing in Thickness Direction (μm) | | | | | | | | | | | | | |
| Evaluation | Reliability | Bridge Generation | ∘ | ∘ | x | ∘ | x | ∘ | ∘ | x | ∘ | ∘ | x |
| | | Electrical Conduction | ∘ | ∘ | ∘ | ∘ | ∘ | ∘ | ∘ | ∘ | ∘ | ∘ | ∘ |
| | | of Counter Electrode | | | | | | | | | | | |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The connecting structure of the present invention is preferably used in producing a semiconductor device.

### DESCRIPTION OF REFERENCE NUMERALS

1 Connecting structure
2 First substrate
3 Adhesive layer
4 Second substrate
5 Anisotropic electrically conductive adhesive film
11 First electrode
12 Second electrode
13 Columnar solder portion
14 Cured resin

1. A connecting structure comprising:
a first substrate having a plurality of first electrodes arranged in a plane direction;
a second substrate having a plurality of second electrodes arranged in the plane direction and disposed at a spaced interval with respect to the first substrate in a thickness direction perpendicular to the plane direction so that the first electrode faces the second electrode; and
an adhesive layer interposed between the first substrate and the second substrate, electrically connecting the first electrode and the second electrode facing each other in the thickness direction, and adhering the first substrate to the second substrate, wherein
a thickness of the adhesive layer is below 15 μm, and
a distance between the first electrodes adjacent to each other in the plane direction is longer than the distance between the first electrode and the second electrode facing each other in the thickness direction.

2. The connecting structure according to claim 1, wherein
the adhesive layer is a cured product of an anisotropic electrically conductive adhesive film, and
the adhesive layer includes a columnar solder portion electrically connecting the first electrode and the second electrode facing each other in the thickness direction, and a cured resin.

3. The connecting structure according to claim 1- or 2, wherein
the plurality of first electrodes and the plurality of second electrodes each are disposed as a dot pattern.

4. The connecting structure according to claim 2, wherein
the anisotropic electrically conductive adhesive film includes a solder particle and
an average value of the maximum length of the solder particle is 3 μm or less.

5. The connecting structure according to claim 2, wherein
the anisotropic electrically conductive adhesive film includes a solder particle and
an average value of the maximum length of the solder particle is 2 μm or less.

6. The connecting structure according to claim 2, wherein
the anisotropic electrically conductive adhesive film includes a solder particle and
an average value of the maximum length of the solder particle is 1 μm or less.

7. The connecting structure according to claim 2, wherein
the anisotropic electrically conductive adhesive film includes a solder particle and
the maximum length of the solder particle is 5 μm or less.

8. The connecting structure according to claim 2, wherein
the anisotropic electrically conductive adhesive film includes a solder particle and
the maximum length of the solder particle is 3 μm or less.
